(19) United States
(12) Patent Application Publication
(10) Pub. No.: US 2025/0308573 A1
(43) Pub. Date: Oct. 2, 2025

(54) MEMORY DEVICES WITH FINE-GRAINED COMMAND/ADDRESS TRAINING MODES

(71) Applicant: Micron Technology, Inc., Boise, ID (US)

(72) Inventor: Keun-Soo Song, Yokoyama (JP)

(21) Appl. No.: 19/069,218

(22) Filed: Mar. 4, 2025

Related U.S. Application Data
(60) Provisional application No. 63/571,973, filed on Mar. 29, 2024.

(51) Int. Cl. G11C 11/4076

(52) U.S. Cl. CPC G11C 11/4076

(57) ABSTRACT

A memory device is provided. The memory device includes a plurality of Command/Address (CA) inputs, a plurality of data inputs/outputs (DQs), and a fine-grained CA training mode (CATM) circuit coupled to the CA inputs and coupled to the DQs. The fine-grained CATM circuit is configured to capture a CA sample from the CA inputs and perform a plurality of operations on the CA sample. Each operation is performed on an exclusive subset of the CA sample, and each operation generates an output value. The fine-grained CATM circuit is additionally configured to drive the plurality of output values over the plurality of DQs.

### CROSS-REFERENCE TO RELATED APPLICATION(S)

The present application claims priority to U.S. Provisional Patent Application No. 63/571,973, filed Mar. 29, 2024, the disclosure of which is incorporated herein by reference in its entirety.

### TECHNICAL FIELD

The present disclosure relates to memory devices, particularly to memory devices with fine-grained command/address training modes.

### BACKGROUND

Memory devices are widely used to store information related to various electronic devices such as computers, wireless communication devices, cameras, digital displays, and the like. Memory devices may be volatile or non-volatile and can be of various types, such as magnetic hard disks, random access memory (RAM), read-only memory (ROM), dynamic RAM (DRAM), synchronous dynamic RAM (SDRAM), and others. Information is stored in various types of RAM by charging a memory cell to have different states. Improving RAM memory devices, generally, can include increasing memory cell density, increasing read/write speeds or otherwise reducing operational latency, increasing reliability, increasing data retention, reducing power consumption, or reducing manufacturing costs, among other metrics.

### BRIEF DESCRIPTION OF THE DRAWINGS

FIG. 1 is a table illustrating an example of data input/output (DQ) line outputs, during a command/address training mode (CATM), for memory devices of different interface widths.

FIG. 2 is a table illustrating an example of DQ line outputs, during a fine-grained CATM, for memory devices of different interface widths in accordance with embodiments of the present technology.

FIG. 3 is a block diagram schematically illustrating an apparatus in accordance with embodiments of the present technology.

FIG. 4 is a simplified logic diagram illustrating memory device logic for fine-grained CATM in accordance with embodiments of the present technology.

FIG. 5 is a simplified timing diagram of a memory device performing fine-grained CATM in accordance with embodiments of the present technology.

FIG. 6 is a flowchart illustrating a method of performing fine-grained CATM in accordance with an embodiment of the present technology.

FIG. 7 is a schematic view showing a system that includes a semiconductor device assembly configured in accordance with an embodiment of the present technology.

### DETAILED DESCRIPTION

The electronics industry relies upon continuous innovation in the field of memory devices to meet the global need for higher-functioning technology. This demand calls for more compact designs for memory devices, with greater demands in terms of speed, capacity, etc. In SDRAM memory devices, in which the operation of the memory device's external pin interface is coordinated by an externally supplied clock signal, there is a desire to increase the frequency of the clock signal (and accordingly, increase the speed of the memory device). For example, the Double Data Rate (DDR) SDRAM standard, with which certain memory devices comply, has increased the specified clock frequency with each generation of the standard. DDR-compatible memory devices operate as slow as a 100 MHz clock signal and as fast as a 450 MHz clock signal. It is expected that the clock signals of memory devices will continue to increase in frequency with newer generations of the DDR standard (e.g., DDR6 and beyond) and/or other SDRAM standards.

Since certain memory devices (e.g., DDR memory devices) synchronize their external pin interfaces to an external clock signal, the clock signal and external pin interfaces of those memory devices should be properly aligned. Otherwise, an incorrect signal value may be on a pin interface when the clock signal triggers sampling of the interface (e.g., the memory device may read an incorrect value on the interface). One external pin interface of a memory device, which should be properly aligned to an external clock signal, is the command/address (CA) input of the memory device, over which the memory device receives (e.g., from a host) command and address inputs. The CA input of a memory device is typically a multi-bit interface (e.g., in a DDR5 memory device the CA input is a 14-bit input, represented as CA[13:0], however the input may be other bit widths in other generations of DDR), and each individual CA pin should be properly aligned to the clock signal. Proper alignment of the individual CA pins to the clock signal can be challenging, however, due to variations in the CA pins and where they are placed relative to the clock on the memory device. Other factors that can impact the alignment, at the memory device interface, between individual CA pins and the clock signal include the different routing distances between a host and memory module of the CA signals and clock signal, the distribution of the memory devices on the memory module, the distribution of metal, and power and signal routing through the package, etc. These factors can make it challenging to provide proper alignment between the CA pins and clock signal at each memory device within a memory system, and said challenges can be exacerbated by increasing clock frequencies.

To properly align the external interfaces and the external clock signal of a memory device, memory systems (including, for example, host memory controller, memory modules, and/or memory devices) typically support one or more training modes. During training, the host memory controller and memory devices exchange training data, which the host memory controller and/or memory devices can use to adjust the timing of the interface therebetween. These timing adjustments (e.g., delays incorporated into a signal) can enable proper alignment of the signals on the memory device interfaces. Further, on a multi-bit interface, individual signals may be adjusted differently, such that the entire multi-bit interface is properly aligned at the boundary of the memory device.

In certain memory systems, the training modes may include a CA Training Mode (CATM) used to train the CA signals (e.g., CA[13:0] in a DDR5 memory system). During CATM, a memory device can generate an output value that is based on all of the CA signals (e.g., using a loopback equation that performs a logical combination of the CA signals), and transmit the output value over the data input/output (DQ) lines back to the host memory controller. The host memory controller can then adjust timing between the CA signals, clock signal, and/or other control signals (e.g., a chip select signal) to achieve proper alignment of the signals at the memory device interface.

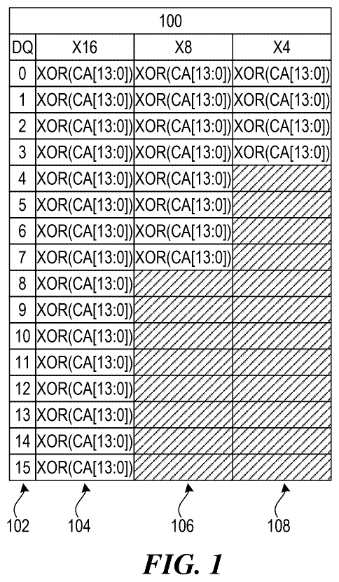

FIG. 1 is a table 100 illustrating an example of DQ line outputs, during CATM, for memory devices of different interface widths. That is, table 100 illustrates the values a memory device transmits over the DQs 102 during CATM. As illustrated in table 100, the number of DQs 102 of a memory device depends on the configuration of the memory device (e.g., based on the number of banks of the memory device, how the banks are arranged, etc.). For example, a memory device in an ×16 configuration 104 (having an ×16 interface width) has 16 DQs (e.g., DQ0-DQ15), a memory device in an ×8 configuration 106 (having an ×8 interface width) has 8 DQs (e.g., DQ0-DQ7), and a memory device in an ×4 configuration 108 (having an ×4 configuration width) has 4 DQs (e.g., DQ0-DQ3). In the table 100, there are fourteen CAs in the illustrated potential memory devices, although, in other potential embodiments, this number can be greater or smaller. When in an ×16 configuration 104, an ×8 configuration 106, or an ×4 configuration 108, an operation can be performed on the CA signals sampled from the fourteen CA pins. The operation can be an XOR operation, as illustrated in the table 100. As the table 100 illustrates, the operation is performed on samples from every CA signal sent to every CA pin on the memory device, and the result of this operation is sent over every available DQ 102 to the memory device and/or to the host controller, according to the configuration.

Conventional CATM, as illustrated in FIG. 1, suffers from various shortcomings. As illustrated in FIG. 1, the result of the same operation (e.g., the XOR of all CA signals) is output by the memory device over every DQ 102. That is, over every DQ 102 the host memory controller receives a value that is a logical combination (e.g., XOR) of all CA signals. Because the host memory controller receives a value that is a logical combination of all CA signals, it may be challenging for the host memory controller to be able to determine the timing associated with any individual CA signal. For example, the host memory controller may be limited to sensitizing, and observing the needed timing adjustments, for just a few CA signals at a time (e.g., one CA signal at a time). As a result, more samples of CA signals (and associated logical combinations) may be required to determine the timing, and needed timing adjustments, of each of the individual CA signals. Thus the time spent in CATM, before normal operation of the memory system commences, may be lengthy. To address these drawbacks and others, various embodiments of the present disclosure provide memory systems (including, e.g., host memory controllers and memory devices) with fine-grained CATM.

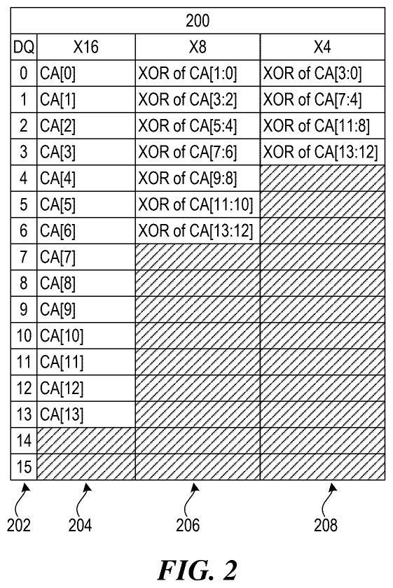

FIG. 2 is a table 200 illustrating an example of DQ line outputs, during fine-grained CATM, for memory devices of different interface widths in accordance with embodiments of the present technology. That is, table 200 illustrates the values a memory device transmits over DQs 202 during fine-grained CATM. As described herein, when in fine-grained CATM the memory device samples the plurality of CAs (e.g., as driven by a host memory controller) during a capture (e.g., when a chip select signal positively or negatively asserts), performs operations on the sampled CAs (e.g., one or more XOR operations), and sends the results of the operations over the DQs 202 back to the host memory controller. Furthermore, the memory device with fine-grained CATM groups sampled CAs into subsets (e.g., a 14-bit CA, represented as CA[13:0], may be grouped into subsets comprised of CA[3:0], CA[7:4], CA[11:8], and CA[13:12]). In some embodiments, at least one exclusive subset of the CA sample includes at most one CA input. The memory device with fine-grained CATM then performs an operation on each of the subsets (e.g., it performs the XOR of each subset separately). The memory device with fine-grained CATM then sends the results of the different operations, performed on different subsets of the sampled CAs, over the DQs 202 to the host memory controller. That is, each DQ 202 is used to send a value (e.g., XOR result) based on different CA signals. In some embodiments, at most one DQ 202 is used to drive the result of an operation performed on a subset of the sampled CAs. In contrast, and as illustrated in FIG. 1, a memory device during conventional CATM sends the same value, based on an operation performed on all CA signals, over all of the DQs. Accordingly, in comparison to conventional CATM, memory devices performing fine-grained CATM send a greater amount of training information per CA capture, and therefore reduce overall training time in CATM.

As illustrated in table 200, the number of DQs 202 of a memory device depends on the configuration of the memory device (e.g., based on the plurality of banks of the memory device, how the banks are arranged, etc.). For example, a memory device in an ×16 configuration 204 (having an ×16 interface width) has 16 DQs (e.g., DQ0-DQ15), a memory device in an ×8 configuration 206 (having an ×8 interface width) has 8 DQs (e.g., DQ0-DQ7), and a memory device in an ×4 configuration 208 (having an ×4 configuration width) has 4 DQs (e.g., DQ0-DQ3). In embodiments, memory devices performing fine-grained CATM may have other configurations with other interface widths. Further, while table 200 illustrates an embodiment in which a memory device performing fine-grained CATM has 14 CA pins (e.g., CA[13:0]), in some embodiments the memory devices may have different numbers of CA pins.

The memory device with fine-grained CATM can perform different operations on each subset of CAs based on the number of CAs in each subset. For example, in the case that a subset has only one CA assigned to it, the operation performed on samples from the one CA can be an identity function (as illustrated in the table 200 for the memory device with an X16 configuration 204, in which an individual CA bit is sent over each DQ 202). In other cases, where a subset has more than one CA assigned to it, samples from those CAs in the subset can have an XOR operation performed on them (as illustrated for the memory device in the X8 configuration 206 and/or for the memory device in the X4 configuration 208, where the result of an XOR operation performed on different subsets of CAs is sent over each DQ 202). As illustrated in table 200, the number of CAs in each subset can depend on the configuration of the memory device (including the number of DQs 202 of the memory device). For example, as illustrated in table 200, a memory device with an X8 configuration 206 has twice the number of DQs 202 as a memory device with an ×4 configuration 208, and therefore each subset has half the number of CAs assigned to the subset. The number of CAs in a subset may also depend on the width of the CA interface between the memory device and host memory controller.

CA subsets can be formed contiguously, as illustrated—that is, CAs zero through three can form subset zero (e.g., row zero in table 200), CAs four through seven can form subset one (e.g., row one in table 200), and so on. Alternatively, the CAs can be assigned to a subset in a non-contiguous manner, in which case subset zero can comprise CA zero, CA five, and CA nine. Further, CA subsets can comprise equal numbers of CAs, as illustrated, or the number of CAs per subset can vary in the memory device. That is, in embodiments of memory systems with fine-grained CATM, different combinations of CA signals may form subsets, based on e.g., the number of DQs of the memory device, the CA interface width, etc.

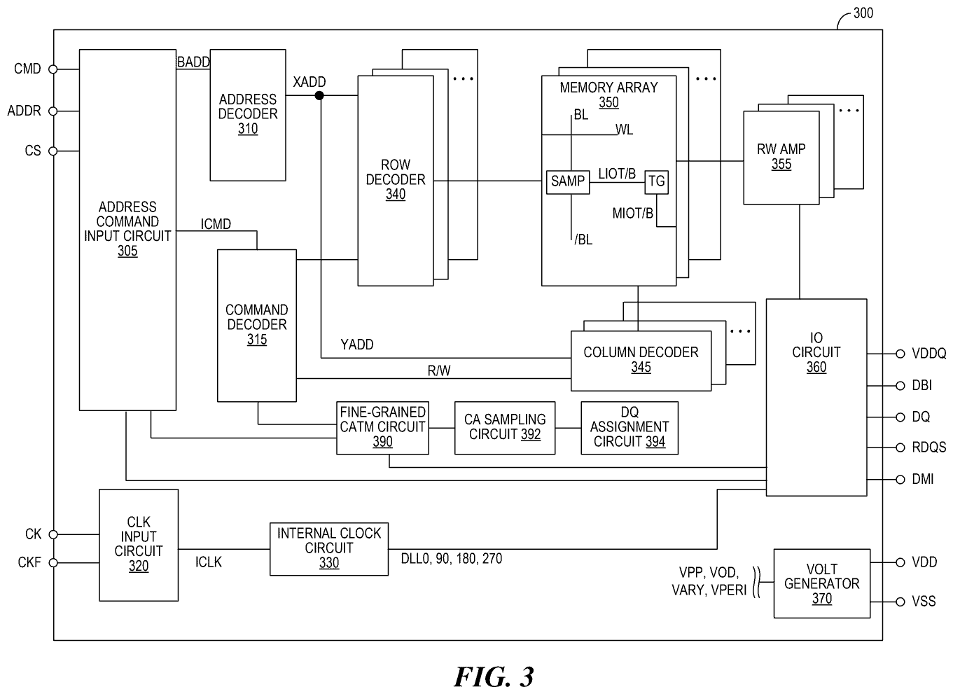

FIG. 3 is a block diagram of an apparatus 300 (e.g., a memory device, a semiconductor die assembly, including a three-dimensional integration (3DI) device or a die-stacked package) in accordance with an embodiment of the present technology. For example, the apparatus 300 can include a DRAM or a portion thereof that includes one or more dies/chips.

The apparatus 300 may include an array of memory cells, such as memory array 350. The memory array 350 may include a plurality of banks (e.g., banks 0-15), and each bank may include a plurality of word lines (WL), a plurality of bit lines (BL), and a plurality of memory cells arranged at intersections of the word lines and the bit lines. Memory cells can include any one of a number of different memory media types, including capacitive, magnetoresistive, ferroelectric, phase change, or the like. The selection of a word line WL may be performed by a row decoder 340, and the selection of a bit line BL may be performed by a column decoder 345. Sense amplifiers (SAMP) may be provided for corresponding bit lines BL and connected to at least one respective local input/output (IO) line pair (LIOT/B), which may, in turn, be coupled to at least a respective one main IO line pair (MIOT/B), via transfer gates (TG), which can function as switches. The sense amplifiers and transfer gates may be operated based on control signals from decoder circuitry, which may include the command decoder 315, the row decoders 340, the column decoders 345, any control circuitry of the memory array 350, or any combination thereof. The memory array 350 may also include plate lines and corresponding circuitry for managing their operation.

The apparatus 300 may employ a plurality of external terminals that include command and address terminals coupled to a command bus and an address bus to receive command signals (CMD) and address signals (ADDR), respectively. The apparatus 300 may further include a chip select terminal to receive a chip select signal (CS), clock terminals to receive clock signals CK and CKF, data clock terminals to receive data clock signals WCK and WCKF, data terminals DQ, RDQS, DBI, and DMI, and power supply terminals VDD, VSS, and VDDQ.

The command terminals and address terminals may be supplied with an address signal and a bank address signal (not shown in FIG. 1) from an outside device (e.g., a host memory controller). The address signal and the bank address signal supplied to the address terminals can be transferred, via a Command/Address input circuit 305, to an address decoder 310. The address decoder 310 can receive the address signals and supply a decoded row address signal (XADD) to the row decoder 340 and a decoded column address signal (YADD) to the column decoder 345. The address decoder 310 can also receive the bank address signal and supply the bank address signal to both the row decoder 340 and the column decoder 345.

The command and address terminals may be supplied with command signals (CMD), address signals (ADDR), and chip select signals (CS) from a memory controller. The command signals may represent various memory commands from the memory controller (e.g., including access commands, which can include read commands and write commands). The chip select signal may be used to select the apparatus 300 to respond to commands and addresses provided to the command and address terminals. When an active chip select signal is provided to the apparatus 300, the commands and addresses can be decoded, and memory operations can be performed. The command signals may be provided as internal command signals ICMD to a command decoder 315 via the Command/Address input circuit 305. The command decoder 315 may include circuits to decode the internal command signals ICMD to generate various internal signals and commands for performing memory operations—for example, a row command signal to select a word line and a column command signal to select a bit line. The command decoder 315 may further include one or more registers for tracking various counts or values (e.g., counts of refresh commands received by the apparatus 300 or self-refresh operations performed by the apparatus 300).

Read data can be read from memory cells in the memory array 350 designated by row address (e.g., address provided with an active command) and column address (e.g., address provided with the read). The read command may be received by the command decoder 315, which can provide internal commands to input/output circuit 360 so that read data can be output from the data terminals DQ, RDQS, DBI, and DMI via read/write amplifiers 355 and the input/output circuit 360 according to the RDQS clock signals. The read data may be provided at a time defined by read latency information RL that can be programmed in the apparatus 300—for example, in a mode register (not shown in FIG. 1). The read latency information RL can be defined in terms of clock cycles of the CK clock signal. For example, the read latency information RL can be a number of clock cycles of the CK signal after the read command is received by the apparatus 300 when the associated read data is provided.

Write data can be supplied to the data terminals DQ, DBI, and DMI according to the WCK and WCKF clock signals. The write command may be received by the command decoder 315, which can provide internal commands to the input/output circuit 360 so that the write data can be received by data receivers in the input/output circuit 360 and supplied via the input/output circuit 360 and the read/write amplifiers 355 to the memory array 350. The write data may be written in the memory cell designated by the row address and the column address. The write data may be provided to the data terminals at a time that is defined by write latency WL information. The write latency WL information can be programmed in the apparatus 300—for example, in the mode register. The write latency WL information can be defined in terms of clock cycles of the CK clock signal. For example, the write latency information WL can be a number of clock cycles of the CK signal after the write command is received by the apparatus 300 when the associated write data is received.

The power supply terminals may be supplied with power supply potentials VDD and VSS. These power supply potentials VDD and VSS can be supplied to an internal voltage generator circuit 370. The internal voltage generator circuit 370 can generate various internal potentials VPP, VOD, VARY, VPERI, and the like based on the power supply potentials VDD and VSS. The internal potential VPP can be used in the row decoder 340, the internal potentials VOD and VARY can be used in the sense amplifiers included in the memory array 350, and the internal potential VPERI can be used in many other circuit blocks.

The power supply terminal may also be supplied with power supply potential VDDQ. The power supply potential VDDQ can be supplied to the input/output circuit 360 together with the power supply potential VSS. The power supply potential VDDQ can be the same potential as the power supply potential VSS in an embodiment of the present technology. The power supply potential VDDQ can be a different potential from the power supply potential VDD in another embodiment of the present technology. However, the dedicated power supply potential VDDQ can be used for the input/output circuit 360 so that power supply noise generated by the input/output circuit 360 does not propagate to the other circuit blocks.

The clock terminals and data clock terminals may be supplied with external clock signals and complementary external clock signals. The external clock signals CK, CKF, WCK, and WCKF can be supplied to a clock input circuit 320. The CK and CKF signals can be complementary, and the WCK and WCKF signals can also be complementary. Complementary clock signals can have opposite clock levels and transition between the opposite clock levels at the same time. For example, when a clock signal is at a low clock level, a complementary clock signal is at a high level, and when the clock signal is at a high clock level, the complementary clock signal is at a low clock level. Moreover, when the clock signal transitions from the low clock level to the high clock level, the complementary clock signal transitions from the high clock level to the low clock level, and when the clock signal transitions from the high clock level to the low clock level, the complementary clock signal transitions from the low clock level to the high clock level.

Input buffers included in the clock input circuit 320 can receive the external clock signals. For example, when enabled by a clock/enable signal from the command decoder 315, an input buffer can receive the clock/enable signals. The clock input circuit 320 can receive the external clock signals to generate internal clock signals ICLK. The internal clock signals ICLK can be supplied to an internal clock circuit 330. The internal clock circuit 330 can provide various phase and frequency controlled internal clock signals based on the received internal clock signals ICLK and a clock enable (not shown in FIG. 1) from the Command/Address input circuit 305. For example, the internal clock circuit 330 can include a clock path (not shown in FIG. 1) that receives the internal clock signal ICLK and provides various clock signals to the command decoder 315. The internal clock circuit 330 can further provide input/output (IO) clock signals. The IO clock signals can be supplied to the input/output circuit 360 and can be used as timing signals for determining the output timing of read data and/or input timing of write data. The IO clock signals can be provided at multiple clock frequencies so that data can be output from and input to the apparatus 300 at different data rates. A higher clock frequency may be desirable when high memory speed is desired. A lower clock frequency may be desirable when lower power consumption is desired. The internal clock signals ICLK can also be supplied to a timing generator 335, and thus various internal clock signals can be generated.

The apparatus 300 can be connected to any one of a number of electronic devices capable of utilizing memory for the temporary or persistent storage of information or a component thereof. For example, a host device of apparatus 300 may be a computing device, such as a desktop or portable computer, a server, a handheld device (e.g., a mobile phone, a tablet, a digital reader, a digital media player), or some component thereof (e.g., a central processing unit, a coprocessor, a dedicated memory device, etc.). The host device may be a networking device (e.g., a switch, a router, etc.) or a recorder of digital images, audio and/or video, a vehicle, an appliance, a toy, or any one of a number of other products. In one embodiment, the host device may be connected directly to apparatus 300, although in other embodiments, the host device may be indirectly connected to a memory device (e.g., over a networked connection or through intermediary devices).

The apparatus 300 can include a fine-grained CATM circuit 390. The fine-grained CATM circuit 390 can be coupled to Command/Address (CA) inputs (e.g., signals from the command and address terminals coupled to the command bus and the address bus). For example, the fine-grained CATM circuit 390 can receive these CA inputs from the Command/Address input circuit 305 and/or the command decoder 315. The fine-grained CATM circuit 390 can also be coupled to data inputs/outputs (DQs), and/or one or more other data terminals (e.g., RDQS, DBI, and/or DMI). This coupling can be achieved through an intermediary circuit—e.g., the input/output circuit 360, as illustrated in FIG. 3.

As described above, the command decoder 315 is coupled to the CA inputs and can decode one or more commands (e.g., from a memory controller) sent on the CA interface. For example, the command decoder 315 can detect a CATM enter command and/or a fine-grained CATM enter command. When the command decoder 315 detects a CATM enter command and/or a fine-grained CATM enter command, it can send a signal to the fine-grained CATM circuit 390. The CATM enter command can include a multi-purpose command (MPC) with an op-code of 0000 0011b. The apparatus 300 (e.g., a memory device) can be configured for on-die termination (ODT) in order to reduce reflections on the CA inputs, as well as on the CK signal and CS signal. This configuration can include resistive termination located approximately or adjacent to the fine-grained CATM circuit 390. Additionally, in some embodiments, the fine-grained CATM circuit can exit the CATM in response to receiving a CATM exit indication. In some embodiments, receiving the CATM exit indication can include asserting the CS signal for two cycles of the CK signal.

The fine-grained CATM circuit 390 is configured to capture a CA sample from the CA inputs. This can be done by the fine-grained CATM circuit 390 or delegated to a sub-circuit, e.g., a CA sampling circuit 392. The fine-grained CATM circuit 390 is also configured to perform an operation on the CA sample. The CA sample can be divided into exclusive subsets, in which case the operation can be performed on each subset, generating an output value for each operation and, by extension, each subset. The operation that is performed can depend on a configuration of banks in the memory array 350 (e.g., how many DQs of the apparatus 300), the width of the CA sample, and how the CA sample is divided into subsets. For example, at least one exclusive subset of the CA sample can include one CA input. In such embodiments, the operation performed on the at least one exclusive subset may be an identity function. As a separate example, at least one exclusive subset of the CA sample can include more than one CA input. In embodiments of this type, the operation performed on the at least one exclusive subset may be an exclusive-or function.

In some embodiments, the apparatus 300 includes a clock input (CK) with a rising edge and a chip select input (CS). In such embodiments, the CS input is aligned to the CK input, and the fine-grained CATM circuit captures the CA sample based on the CS input and the CK input. For example, the fine-grained CATM circuit can capture the CA sample when the chip select input is asserted low on a rising edge of the clock input. Alternatively, when the CS input is asserted high, the fine-grained CATM circuit can hold the CA sample. In embodiments, the fine-grained CATM circuit holds the CA sample for a maximum number of clock cycles (e.g., four clock cycles). By holding a CA sample, the apparatus 300 and/or fine-grained CATM circuit 390 can continue to send the results (over the DQs) of operations performed on a previously-captured CA sample, without being sensitive to changes on the CA interface.

In embodiments in which the apparatus 300 (e.g., a memory device) comprises fourteen CA inputs and four DQs, an exclusive-or operation is performed on four exclusive subsets of the CA sample to generate four output values. In these embodiments, three of the four exclusive subsets include four CA inputs, and one exclusive subset includes two CA inputs. Furthermore, the fine-grained CATM circuit is configured to drive each of the four output values over a different DQ. In other embodiments in which the memory device comprises fourteen CA inputs and eight DQs, an exclusive-or operation is performed on seven exclusive subsets of the CA sample to generate seven output values. Additionally, in these embodiments, each exclusive subset comprises two CA inputs and the fine-grained CATM circuit 390 drives each of the seven output values over a different DQ. In yet another potential embodiment, the memory device can include fourteen CA inputs and sixteen DQs, in which case an identity operation is performed on fourteen exclusive subsets of the CA sample to generate fourteen output values. Continuing with this embodiment, the fourteen exclusive subsets include one CA input, and the fine-grained CATM circuit 390 drives each of the fourteen output values over a different DQ.

The fine-grained CATM circuit 390 is also configured to drive these output values over the DQs. In some embodiments, at least one output value is driven on one DQ. In other embodiments, the same output value can be driven on more than one DQ. Additionally, assignments between output values and DQs can be made by a DQ assignment circuit 394 or by the fine-grained CATM circuit 390 itself.

Although FIG. 3 illustrates an embodiment of the apparatus 300 in which the fine-grained CATM circuit 390, CA sampling circuit 392, and DQ assignment circuit 394 are illustrated as different components, in some embodiments, one or more of the aforementioned circuits and/or sensors can be combined. For example, in some embodiments, the DQ assignment circuit 394 and CA sampling circuit 392 are a single circuit that performs both CA sampling and DQ assigning functions. Although FIG. 3 illustrates an embodiment of the apparatus 300 with a single CA sampling circuit 392 and DQ assignment circuit 394, in some embodiments, the apparatus includes multiple samplers, assigners, and fine-grained CATM circuits.

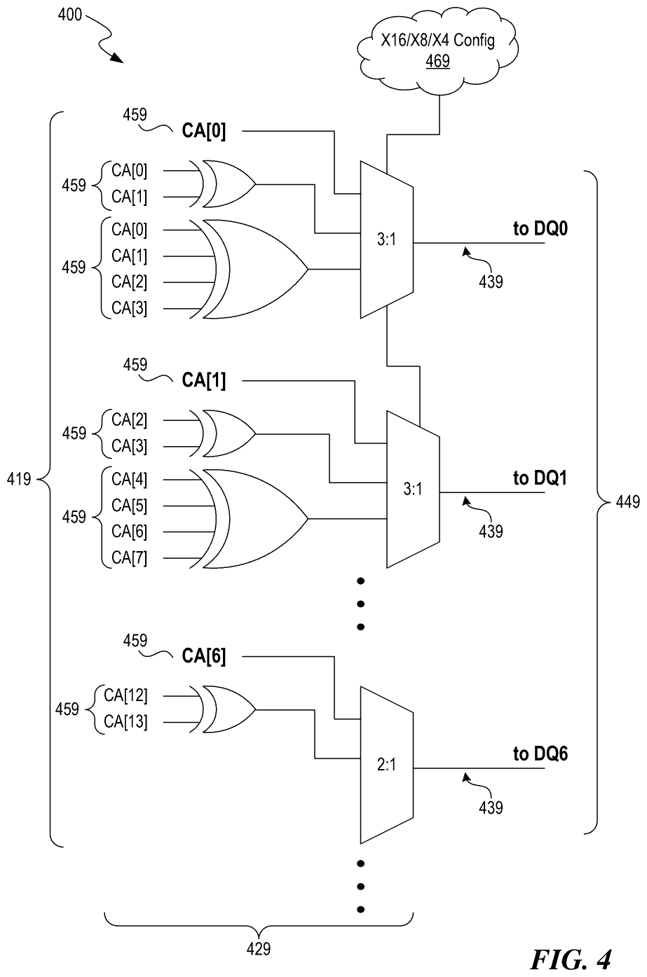

FIG. 4 is a simplified logic diagram illustrating memory device logic 400 for fine-grained CATM in accordance with embodiments of the present technology. For example, the logic 400 may be part of the apparatus 300 illustrated in FIG. 3 (e.g., part of the fine-grained CATM circuit 390, CA sampling circuit 392, and/or DQ assignment circuit 394). As described herein, the logic 400 may facilitate performing operations on subsets of CA signals, based on the configuration of the memory device, and sending the operation results over DQs (e.g., performing the function of table 200 illustrated in FIG. 2).

The logic 400 can include receiving Command/Address (CA) inputs 419, combinational logic (e.g., logic gates such as XOR gates, multiplexors, etc.) 429 to performing operations on the inputs 419, and driving resulting output values 439 over data inputs/outputs (DQs) 449.

The operation that is performed can depend on a configuration 469 of the memory device and how the CA sample is divided into subsets 459. That is, as illustrated in FIG. 4, the combinational logic 429 can include a plurality of XOR gates to compute the XOR result of different subsets 459 of the CA inputs 419. The combinational logic 429 can additionally include multiplexors, each associated with a DQ 449, that selects which XOR result to send over the associated DQ 449 based on the configuration 469 of the memory device. That is, one multiplexor input may be associated with an ×16 configuration, one multiplexor input may be associated with an ×8 configuration, and one multiplexor input may be associated with a ×4 configuration. For example, as illustrated in FIG. 4, the multiplexor associated with DQ0 receives as inputs CA[0] (for when the memory device is in an ×16 configuration), XOR(CA[1:0]) (for when the memory device is in an ×8 configuration), and XOR (CA[3:0]) (for when the memory device is in an ×4 configuration). In embodiments the logic 400 can include additional combinational logic 429, or different arrangements of the combinational logic, to facilitate performing different operations on different subsets 459 of CA inputs 419, to be sent to different DQs 449, depending on the number of CA inputs, the number of DQs, desire for different operations, etc.

In some embodiments at least one exclusive subset 459 of the CA sample can include one CA input 419. In such embodiments, the operation performed by the combinational logic 429 on the at least one exclusive subset 459 is an identity function. As a separate example, in some embodiments at least one exclusive subset 459 of the CA sample can include more than one CA input 419. In embodiments of this type, the operation performed by the combinational logic 429 on the at least one exclusive subset 459 is an exclusive-or function.

Specifically, in those embodiments in which the logic 400 receives fourteen CA inputs 419 to be sent over four DQs 449, the operation performed by the combinational logic 429 is an exclusive-or operation. In such an embodiment, the operation performed by the combinational logic 429 is performed on four exclusive subsets 459 of the CA sample to generate four output values 439. The logic 400 can include driving each of the four output values 439 over a different DQ 449. In some embodiments, at least one output value 439 is driven on one DQ 449. In other embodiments, the same output value 439 can be driven on more than one DQ 449.

Additionally, three of the four exclusive subsets 459 can include four CA inputs 419, and one exclusive subset 459 includes two CA inputs 419. In other embodiments in which the memory device comprises fourteen CA inputs 419 and eight DQs 449, an exclusive—or operation is performed on seven exclusive subsets 459 of the CA sample to generate seven output values 439. Additionally, in these embodiments, each exclusive subset 459 includes two CA inputs 419, and the method includes driving each of the seven output values 439 over a different DQ 449. In yet another potential embodiment, the method includes fourteen CA inputs 419 and sixteen DQs 449, in which case the operation performed by the combinational logic 429 is an identity operation. The identity operation is performed on the fourteen exclusive subsets 459 of the CA sample to generate fourteen output values 439. Continuing with this embodiment, each one of the fourteen exclusive subsets 459 includes one CA input 419, and the method includes driving each of the fourteen output values 439 over a different DQ 449.

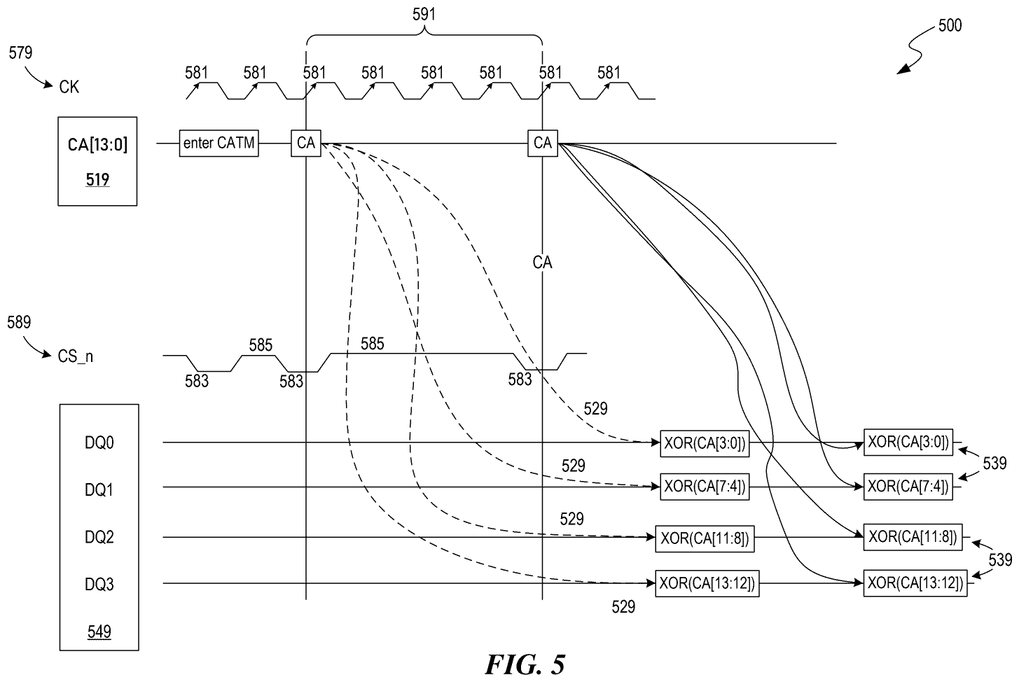

FIG. 5 is a simplified timing diagram 500 of a memory device that is performing fine-grained CATM in accordance with embodiments of the present technology. The memory device receives Command/Address (CA) inputs 519, performs an operation 529 on the CA inputs 519, and drives resulting output values 539 over data inputs/outputs (DQs) 549. FIG. 5 illustrates the timing diagram 500 for a memory device in an ×4 configuration (e.g., it has 4 DQs 549, labeled DQ0-DQ3) with a 14-bit CA input 519 (labeled CA[13:0]), but in other embodiments the memory device may have a different width of CA inputs 519 and/or a different number of DQs 549.

The memory device can receive additional inputs, including a clock (CK) input 579 with a rising edge 581, and a chip select (CS) input 589. In such embodiments, the CS input 589 is aligned with the CK input 579. Further, the CA inputs 519 can include a Command/Address Training Mode (CATM) enter command, a multi-purpose command (MPC), or commands with an op-code of 0000 0011b. In some embodiments, the CA inputs 519 include a CATM exit indication.

As illustrated in FIG. 5, the CA inputs 519 can include a MPC (e.g., driven by a host memory controller) to instruct the memory device to enter fine-grained CATM (e.g., an enter CATM or enter fine-granted CATM command). The memory device may also receive, from the host memory controller, a CATM exit indication (not shown). As described below, once in fine-grained CATM the memory device will sample the CA inputs 519 and perform operations 529 on the CA inputs as instructed by the host controller. In some embodiments, the host memory controller instructs the memory device to exit CATM by asserting the CS input 589 for two cycles of the CK signal.

When in fine-grained CATM, the memory device can capture a sample of CA inputs 519 based on the CS input 589 and the CK input 579. For example, the host memory controller may assert low 583 (e.g., de-assert) CS input 589, based on which the memory device can capture the CA sample on the next rising edge 581 of the CK input 579. In some embodiments, when the CS input 589 is asserted high 585, the memory device holds the operation result of the previously-captured CA sample, as illustrated by a holding period 591. While in the holding period 591, the memory device prevents the output values 539 from changing from the output values generated based on the previously-sampled CA input 519. The CA sample can be divided into exclusive subsets, in which case the operation 529 can be performed on each subset, generating an output value 539 for each operation and, by extension, each subset.

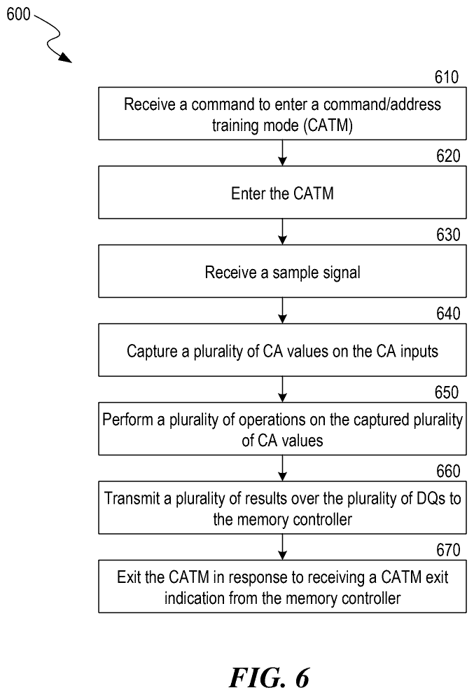

FIG. 6 is a flowchart illustrating a method 600 of making a semiconductor device assembly. The method includes receiving, at a memory device, a command from a memory device coupled to the memory device to enter a Command/Address Training Mode (CATM), wherein the memory device comprises a fine-grained CATM circuit, a plurality of Command/Address (CA) inputs, and a plurality of data inputs/outputs (DQs) wherein the fine-grained CATM circuit is coupled to the plurality of CA inputs and to the DQs (box 610). The method includes entering, in response to receiving the command, the CATM (box 620). The method includes receiving a sample signal (box 630). The method includes capturing, in response to receiving the sample signal, a plurality of CA values on the CA inputs (box 640). The method includes performing a plurality of operations on the captured plurality of CA values, wherein each operation of the plurality is performed on a different subset of the plurality of CA values (box 650). The method includes transmitting over the plurality of DQs a plurality of results to the memory device, wherein each operation yields each result and wherein each result is transmitted over a different DQ (box 660). The method includes exiting the CATM in response to receiving a CATM exit indication from the memory device (box 670).

In accordance with one aspect of the present disclosure, the semiconductor devices illustrated in the assemblies of FIGS. 3-4 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.) or a mix of logic and memory dies (e.g., a memory device die and a memory die controlled thereby).

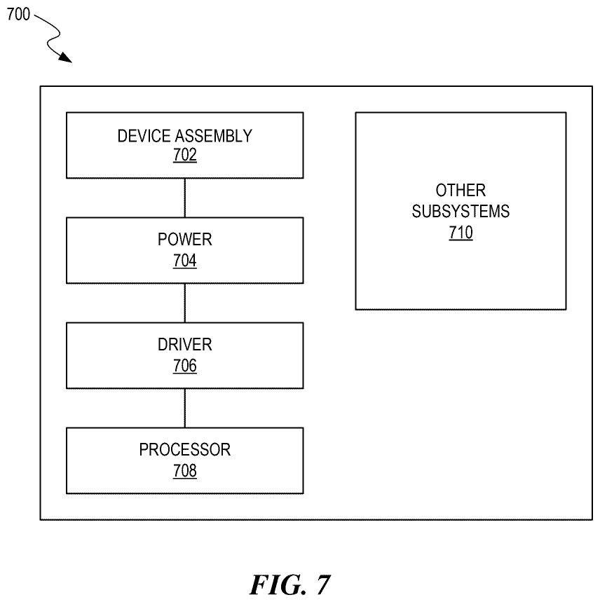

Any one of the semiconductor devices and semiconductor device assemblies described above with reference to FIGS. 3-4 can be incorporated into any of a myriad of larger and/or more complex systems, a representative example of which is system 700 shown schematically in FIG. 7. The system 700 can include a semiconductor device assembly (e.g., or a discrete semiconductor device) 702, a power source 704, a driver 706, a processor 708, and/or other subsystems or components 710. The semiconductor device assembly 702 can include features generally similar to those of the semiconductor devices described above with reference to FIGS. 2-6. The resulting system 700 can perform any of a wide variety of functions, such as memory storage, data processing, and/or other suitable functions. Accordingly, representative systems 700 can include, without limitation, handheld devices (e.g., mobile phones, tablets, digital readers, and digital audio players), computers, vehicles, appliances, and other products. Components of the system 700 may be housed in a single unit or distributed over multiple interconnected units (e.g., through a communications network). The components of the system 700 can also include remote devices and any of a wide variety of computer-readable media.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species, including, but not limited to, phosphorous, boron, or arsenic. Doping may be performed during the initial formation or growth of the substrate, by ion implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, that the operations and the steps may be rearranged or otherwise modified, and that other implementations are possible. Furthermore, embodiments from two or more of the methods may be combined.

From the foregoing, it will be appreciated that specific embodiments of the invention have been described herein for purposes of illustration but that various modifications may be made without deviating from the scope of the invention. Rather, in the foregoing description, numerous specific details are discussed to provide a thorough and enabling description of embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods, in addition to those specific embodiments disclosed herein, may be within the scope of the present technology.

What is claimed is:

1. A memory device, comprising:
a plurality of command/address (CA) inputs;
a plurality of data inputs/outputs (DQs); and
a fine-grained CA training mode (CATM) circuit coupled to the CA inputs and coupled to the DQs, the fine-grained CATM circuit configured to:
capture a CA sample from the CA inputs;
perform a plurality of operations on the CA sample, wherein each operation is performed on an exclusive subset of the CA sample;
generate a plurality of output values, wherein each operation generates an output value; and
drive the plurality of output values over the plurality of DQs.

2. The memory device of claim 1, wherein the exclusive subset of the CA sample comprises at least one CA input, and wherein at least one of the output values generated by the operation performed on the exclusive subset is driven on at most one DQ.

3. The memory device of claim 1, wherein the memory device comprises fourteen CA inputs and four DQs, wherein an exclusive-or operation is performed on four exclusive subsets of the CA sample to generate four output values, wherein three of the four exclusive subsets comprise four CA inputs and one comprises two CA inputs, and wherein the fine-grained CATM circuit is configured to drive each of the four output values over a different DQ.

4. The memory device of claim 1, wherein the memory device comprises fourteen CA inputs and eight DQs, wherein an exclusive-or operation is performed on seven exclusive subsets of the CA sample to generate seven output values, wherein each exclusive subset comprises two CA inputs, and wherein the fine-grained CATM circuit is configured to drive each of the seven output values over a different DQ.

5. The memory device of claim 1, wherein the memory device comprises fourteen CA inputs and sixteen DQs, wherein an identity operation is performed on fourteen exclusive subsets of the CA sample to generate fourteen output values, wherein the fourteen exclusive subsets comprise one CA input, and wherein the fine-grained CATM circuit is configured to drive each of the fourteen output values over a different DQ.

6. The memory device of claim 1, wherein the memory device further comprises a plurality of banks, and wherein the fine-grained CATM circuit is further configured to:
determine a configuration of the plurality of banks,
wherein the exclusive subset of the CA sample on which each operation is performed is based on the determined configuration.

7. The memory device of claim 1, wherein the memory device further comprises a clock input with a rising edge and a chip select input, wherein the chip select input is aligned to the clock input, and wherein the fine-grained CATM circuit is further configured to capture the CA sample based on the chip select input and the clock input.

8. The memory device of claim 7, wherein the fine-grained CATM circuit is further configured to capture the CA sample when the chip select input is asserted low on a rising edge of the clock input.

9. The memory device of claim 7, wherein the chip select input is a first chip select input, and wherein the fine-grained CATM circuit is further configured to:
receive a second chip select input; and
based on the second chip select input, hold the CA sample for a maximum of four clock cycles, wherein the second chip select input is asserted high.

10. The memory device of claim 1, wherein at least one exclusive subset of the CA sample comprises at most one CA input, and wherein the operation performed on the at least one exclusive subset is an identity function.

11. The memory device of claim 1, wherein at least one exclusive subset of the CA sample comprises more than one CA input, and wherein the operation performed on the at least one exclusive subset is an exclusive-or function.

12. The memory device of claim 1, wherein the memory device further comprises a command decoder that is coupled to the CA inputs and coupled to the fine-grained CATM circuit, wherein the command decoder is configured to detect a command/address Training Mode (CATM) enter command on the CA inputs, and wherein the fine-grained CATM circuit is further configured to detect the CATM enter command from the command decoder.

13. The memory device of claim 12, wherein the CATM enter command comprises a multi-purpose command (MPC) with an op-code of 0000 0011b.

14. The memory device of claim 1, wherein the memory device further comprises an IO circuit coupled to the fine-grained CATM circuit and coupled to the DQs.

15. The memory device of claim 1, wherein the memory device is configured for on-die termination (ODT).

16. A method for fine-grained Command/Address training on a memory device coupled to a plurality of command/address (CA) inputs and to a plurality of data inputs/outputs (DQs), the method comprising:
receiving a command to enter a command/address Training Mode (CATM);
in response to receiving the command, entering the CATM;
receiving a sample signal;
in response to receiving the sample signal, capturing a CA sample from the plurality of CA inputs;
performing a plurality of operations on the CA sample, wherein each operation is performed on an exclusive subset of the CA sample;
yielding a plurality of results, wherein each operation yields a result;
transmitting the plurality of results over a plurality of DQs, wherein each result is transmitted over a different DQ; and
exiting the CATM in response to receiving a CATM exit indication.

17. The method of claim 16, wherein the sample signal is a first chip select signal, wherein the memory device further comprises a clock signal with a rising edge, wherein the chip select signal is aligned with the clock signal, wherein capturing the CA sample occurs when the chip select signal is asserted low on a rising edge of the clock signal, and wherein the method further comprises:
receiving a second chip select signal; and
based on the second chip select signal, holding the CA sample for a maximum of four clock cycles,
wherein the second chip select signal is asserted high.

18. The method of claim 16, wherein the memory device further comprises a plurality of banks, and wherein performing a plurality of operations further comprises:
determining a configuration of the plurality of banks,
wherein the exclusive subset of the CA sample on which each operation is performed is based on the determined configuration.

19. The method of claim 16, wherein at least one exclusive CA subset comprises at most one CA value, and wherein the operation performed on the at least one exclusive CA subset is an identity function.

20. The method of claim 16, wherein at least one exclusive CA subset comprises more than one CA input, and wherein the operation performed on the at least one exclusive CA subset is an exclusive-or function.
